(19) United States
(12) Patent Application Publication
(10) Pub. No.: US 2013/0009239 A1
(43) Pub. Date: Jan. 10, 2013

(54) 3-D NON-VOLATILE MEMORY DEVICE AND METHOD OF MANUFACTURING THE SAME

(76) Inventors: Ki Hong LEE, Gyeonggi-do (KR); In Su Park, Chungbuk (KR)

(21) Appl. No.: 13/542,853

(22) Filed: Jul. 6, 2012

(30) Foreign Application Priority Data
Jul. 6, 2011 (KR) 10-2011-0066811

(51) Int. Cl. H01L 29/78; H01L 21/336

(52) U.S. Cl. 257/330; 438/270; 257/E29.262; 257/E21.41

(57) ABSTRACT

A 3-D non-volatile memory device includes a pipe gate having a first trench formed therein, word lines stacked in multiple layers over the pipe gate, second trenches coupled to the first trench and formed to penetrate the word lines, a first channel layer formed within the first trench, and second channel layers formed within the second trenches, respectively, and coupled to the first channel layer, wherein the width or depth of the first trench is smaller than the diameter of each of the second trenches.

### CROSS-REFERENCE TO RELATED APPLICATION

Priority to Korean patent application number 10-2011-0066811 filed on Jul. 6, 2011, the entire disclosure of which is incorporated by reference herein, is claimed.

### BACKGROUND

Exemplary embodiments relate to a semiconductor device and a method of manufacturing the same and, more particularly, to a 3-Dimensional (3-D) non-volatile memory device and a method of manufacturing the same.

A non-volatile memory device retains data although the supply of power is stopped. As 2-D memory devices in which memory cells are fabricated over a silicon substrate in a single layer reach the limit in increasing their degree of integration, there is proposed a 3-D non-volatile memory device in which memory cells are vertically stacked from a silicon substrate.

The structure and features of a known 3-D non-volatile memory device are described below with reference to the accompanying drawings.

FIG. 1 is a cross-sectional view of a conventional 3-D non-volatile memory device.

First, a method of manufacturing the conventional 3-D non-volatile memory device is simply described with reference to FIG. 1.

As shown in FIG. 1, a first interlayer insulating layer 11 and a pipe gate 12 are formed over a substrate 10.

The pipe gate 12 is etched to form a trench for a pipe channel. A sacrificial layer (not shown) is filled in the trench for a pipe channel.

Next, word lines 13 and second interlayer insulating layers 14 are alternately formed over the pipe gate 12 and then etched to form a pair of trenches for memory channels coupled to the trench for a pipe channel.

After removing the sacrificial layer filled in the trench for a pipe channel, a charge blocking layer, a charge trapping layer, and a tunnel insulating layer (hereinafter collectively denoted by reference numeral 15) are formed on the internal surfaces of the trench for a pipe channel and the pair of trenches for memory channels. A layer 16 for a channel is formed on the tunnel insulating layer, thereby forming a pipe channel layer CH_P within the trench for a pipe channel and a pair of memory channel layers CH_M within the trenches for memory channels. The pipe channel layer CH_P and the pair of memory channel layers CH_M form one channel CH.

The word lines 13 and the second interlayer insulating layers 14 are etched to form slits. An insulating layer 17 is filled in the slits.

In accordance with the above structure, in the process of forming the layer 16 for a channel, the layer 16 may be filled in the bottom parts of the trenches for memory channels, that is, parts III of FIG. 2A where the trench for a pipe channel and the trenches for memory channels are coupled, before fully filled in the trench for a pipe channel. Accordingly, an empty space 19 may be formed within the pipe channel layer CH_P. These features of the conventional 3-D non-volatile memory device are described in more detail below with reference to FIGS. 2A and 2B.

FIGS. 2A and 2B are enlarged views of the pipe channel region of the 3-D non-volatile memory device shown in FIG. 1. FIG. 2A is a cross sectional view of the pipe channel region taken along line I-I′ of FIG. 1, and FIG. 2B is a perspective view of a region II in FIG. 1.

As shown in FIGS. 2A and 2B, the conventional 3-D non-volatile memory device includes the trench for a pipe channel having a width W1 greater than the diameter W2 of each of the trenches for memory channels.

In a known art, the trench for a pipe channel is formed to have a width W1 great enough to secure a margin when subsequently forming the trenches for memory channels. For this reason, in the process of forming the layer 16 for a channel, the parts III where the trench for a pipe channel and the trenches for memory channels are coupled are filled with the layer 16 before the trench for a pipe channel is filled. Thus, the empty space 19 may be formed within the pipe channel layer CH_P. Therefore, the layer 16 for a channel may be partially disconnected because the layer 16 for a channel is agglomerated due to the empty space 19 in a subsequent high-temperature thermal treatment process. If the layer 16 for a channel is partially disconnected, the memory cells may not operate properly because cell current does not smoothly flow into the pipe channel.

In order to prevent the coupling parts III from being filled, there is proposed a method of controlling the deposition thickness of the layer 16 for a channel. If the thickness of the layer 16 for a channel is thin, however, it is difficult to secure the proper performance of the memory device. There is a limit in controlling the deposition thickness of the layer 16.

Moreover, since the number of stacked memory cells is increased according to an increase in the degree of integration of memory devices, the inner wall of the trench for a memory channel has an inclined profile owing to the limits of the etch process. That is, the width of the coupling part III is further narrowed because the trench for a memory channel is downwardly narrowed. Accordingly, the empty space 19 may be easily formed within the pipe channel layer CH_P to be more severe.

### BRIEF SUMMARY

Exemplary embodiments relate to a 3-D non-volatile memory device and a method of manufacturing the same, wherein an empty space is not formed within a pipe channel.

A 3-D non-volatile memory device according to an aspect of the present invention includes a pipe gate having a first trench formed therein; word lines stacked in multiple layers over the pipe gate; second trenches coupled to the first trench and formed to penetrate the word lines; a first channel layer formed within the first trench; and second channel layers formed within the second trenches, respectively, and coupled to the first channel layer, wherein the width or depth of the first trench is smaller than the diameter of each of the second trenches.

A method of manufacturing a 3-D non-volatile memory device according to an aspect of the present invention includes forming a first trench by etching a first pipe gate; filling a first sacrificial layer within the first trench; alternately forming first material layers and second material layers over the first pipe gate having the first sacrificial layer filled therein; forming second trenches coupled to the first trench by etching the first material layers and the second material layers; removing the first sacrificial layer exposed at bottoms of the second trenches; and forming a first channel layer within the first trench and forming second channel layers, coupled to the first channel layer within the second trenches, respectively, wherein the width or depth of the first trench is smaller than the diameter of each of the second trenches.

### BRIEF DESCRIPTION OF THE DRAWINGS

FIG. 1 is a cross-sectional view of a conventional 3-D non-volatile memory device;

FIG. 2A is a cross sectional view of the pipe channel region of the conventional 3-D non-volatile memory device shown in FIG. 1;

FIG. 2B is a perspective view of the pipe channel region of the conventional 3-D non-volatile memory device shown in FIG. 1;

FIGS. 3A to 3C are perspective views illustrating a method of manufacturing a 3-D non-volatile memory device according to a first embodiment of the present invention;

FIGS. 4A to 4C are perspective views illustrating a method of manufacturing a 3-D non-volatile memory device according to a second embodiment of the present invention;

FIGS. 5A to 6B are enlarged views of the pipe channel region of the 3-D non-volatile memory device according to the first and the second embodiments of the present invention;

FIG. 7 shows the configuration of a memory system according to an embodiment of the present invention; and

FIG. 8 shows the configuration of a computing system according to an embodiment of the present invention.

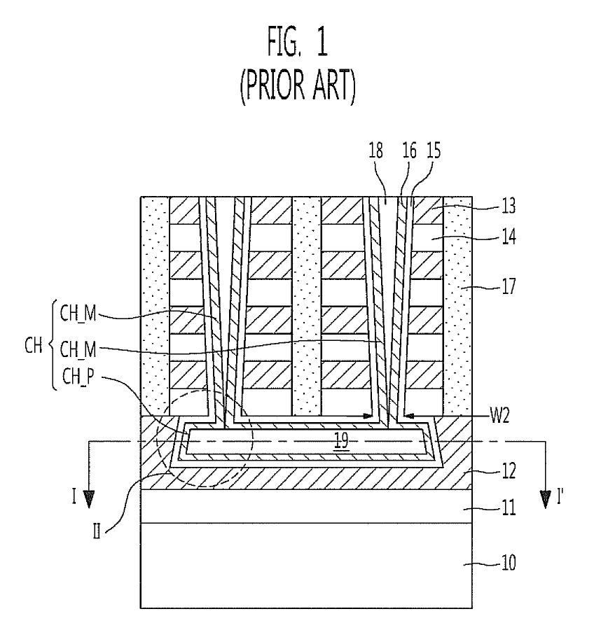

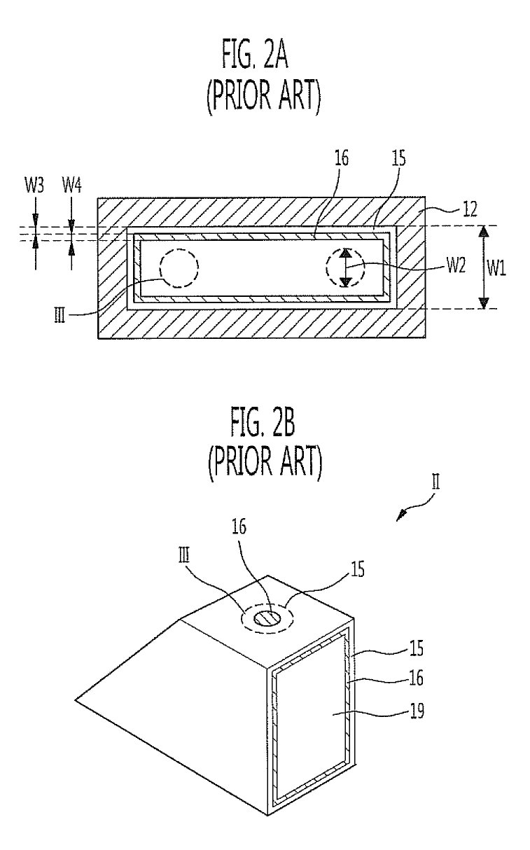

### DESCRIPTION OF EMBODIMENTS

Hereinafter, some exemplary embodiments of the present disclosure will be described in detail with reference to the accompanying drawings. The figures are provided to allow those having ordinary skill in the art to understand the scope of the embodiments of the disclosure.

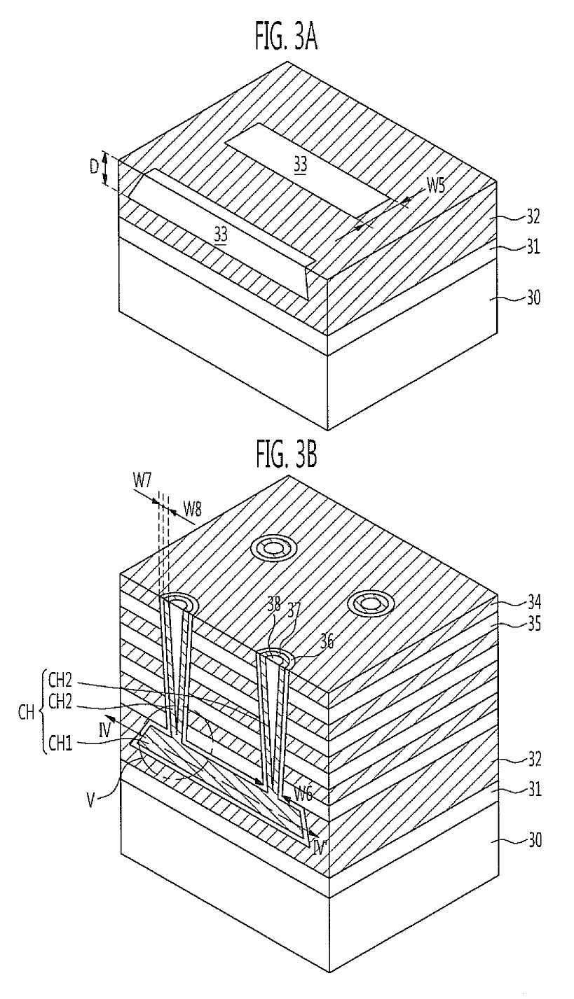

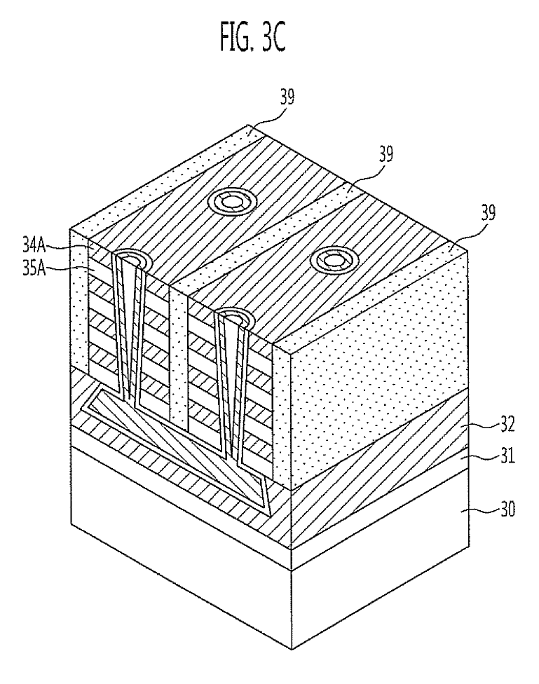

FIGS. 3A to 3C are perspective views illustrating a method of manufacturing a 3-D non-volatile memory device according to a first embodiment of the present invention.

As shown in FIG. 3A, a first interlayer insulating layer 31 and a pipe gate 32 are formed over a substrate 30. The first interlayer insulating layer 31 serves to electrically isolate the substrate 30 and the pipe gate 32 from each other and may be formed of an oxide layer. Furthermore, the pipe gate 32 may be formed of a polysilicon layer.

The pipe gate 32 is etched to form a first trench. The width W5 or depth D of the first trench is formed to be smaller than the diameter W6 of a second trench formed in a subsequent process.

For example, the first trench having the width W5, the first trench having the depth D, or the first trench having the width W5 and the depth D may be formed by etching the pipe gate 32.

For another example, a temporary trench having a greater width or depth than the first trench to be finally formed may be formed by etching the pipe gate 32, and the first trench is finally formed by forming a conductive layer (not shown) or an insulating layer (not shown) on the inside of the temporary trench. If, as described above, the temporary trench is formed and the width and depth of the first trench is controlled using the conductive layer or the insulating layer formed on the temporary trench, the first trench having a width narrower than a minimum value determined by the resolution of a photolithography process may be formed.

The conductive layer may be a polysilicon layer, and it may include impurities having the same type as those of the pipe gate 32. Furthermore, the insulating layer may be formed of an oxide layer. If the insulating layer is formed in the temporary trench, the characteristics of a charge blocking layer may be improved because the insulating layer is interposed between the pipe gate and the charge blocking layer.

A sacrificial layer 33 is filled in the first trench. The sacrificial layer serves to secure a region where a first channel layer is formed in a subsequent process and may be formed of a nitride layer.

Although not shown, a second pipe gate may be further formed on the pipe gate 32 within which the sacrificial layer 33 is filled. When a double gate structure surrounding the entire surface of the pipe channel is formed by further forming the second pipe gate as described above, cell current flowing into the first channel layer and the characteristics of the memory device may be improved.

As shown in FIG. 3B, first material layers 34 and second material layers 35 are alternately formed over the pipe gate 32 within which the sacrificial layer 33 is filled. The number of first material layers 34 and second material layers 35 may be determined by the number of memory cells to be stacked.

The first material layers 34 serve to form word lines or select lines, and the second material layers 35 serve to isolate the word lines or the select lines from each other. The first material layer 34 and the second material layer 35 are made of materials having a high etch selectivity therebetween. For example, the first material layer 34 may be formed of a conductive layer or a sacrificial layer for the word lines, and the second material layer 35 may be formed of an interlayer insulating layer or a sacrificial layer.

For example, the first material layer 34 may be formed of a conductive layer, such as a polysilicon layer, and the second material layer 35 may be formed of an interlayer insulating layer, such as an oxide layer.

For another example, the first material layer 34 may be formed of a doped polysilicon layer or a doped amorphous silicon layer, and the second material layer 35 may be formed of an undoped polysilicon layer or an undoped amorphous silicon layer (i.e., a sacrificial layer). In this case, the second material layer 35 is removed after forming slits. An interlayer insulating layer, such as an oxide layer, is filled in a region from which the second material layer 35 has been removed so that the word lines or the select lines are separated from each other.

For yet another example, the first material layer 34 may be formed of a sacrificial layer, such as a nitride layer, and the second material layer 35 may be formed of an interlayer insulating layer, such as an oxide layer. In this case, the first material layer 34 is removed after forming slits. A conductive layer, such as a polysilicon layer or a tungsten layer, is filled in the region of the first material layer 34, thereby forming the word line.

In the first embodiment, it is described that the first material layer 34 is formed of a conductive layer and the second material layer 35 is formed of an interlayer insulating layer.

The first material layers 34 and the second material layers 35 are etched to form second trenches coupled to the first trench. Each of the second trenches may be formed in a hole shape having a circular section. A pair of the second trenches may be coupled to the first trench. In FIG. 3B, the diameter of the second trench is denoted by ‘W6’. Here, the second trench may be downwardly narrowed owing to a limit to an etch process.

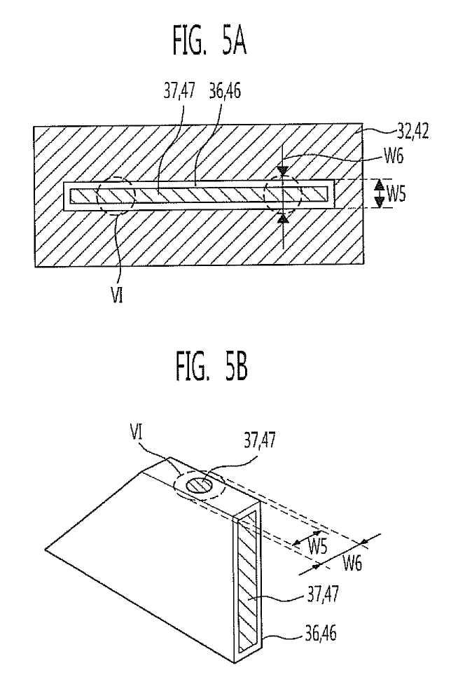

Here, the diameter W6 of the second trench indicates the diameter at the bottom of the second trench (that is, the diameter of a part III of FIGS. 5A and 5B where the first trench and the second trench are coupled).

After removing the sacrificial layer 33 exposed at the bottoms of the second trenches, a memory layer 36 is formed on the inside of the first trench and the second trenches. The memory layer 36 includes a charge blocking layer, a charge trap layer, and a tunnel insulating layer.

A layer 37 for a channel is formed on the memory layer 36, that is, a first channel layer CH1 is formed within the first trench, and second channel layers CH2 are formed within the second trenches. The first channel layer CH1 and the second channel layers CH2 are coupled to form one channel CH.

The width W5 or the depth D of the first trench is smaller than the diameter W6 of the second trench.

Thus, an empty space is not formed within the first trench because the coupling part VI is prevented from being filled before the layer 37 for a channel is fully filled in the first trench when depositing the layer 37 for a channel. Accordingly, the first channel layer CH1 may be formed by fully filling the layer 37 for a channel within the first trench or the first channel layer CH1 may be formed by forming the layer 37 for a channel so that the central region of the first channel layer CH1 is open. Next, an insulating layer may be filled in the open central region of the first channel layer CH1. Here, the second channel layers CH2 may be formed by fully filling the layer 37 for a channel in the second trenches or the second channel layers CH2 each having an open central region may be formed. The insulating layer 38 is filled in the open central region of the second channel layer CH2.

As shown in FIG. 3C, the first material layers 34 and the second material layers 35 are etched to form slits. Thus, word lines 34A stacked in multiple layers are formed over the substrate 30. Here, the word line 34A surrounding a source-side channel (that is, one of a pair of the second channel layers 37) becomes a source-side word line, and the word line 34A surrounding a drain-side channel (that is, the other of a pair of the second channel layers 37) becomes a drain-side word line.

Meanwhile, when forming the word lines 34A, select lines stacked in at least one layer may be formed over the word lines 34A. In some embodiments, after forming the word lines 34A, the select lines may be formed using an additional process.

In FIG. 3C, the second material layers etched when forming the slits are denoted by reference numeral ‘35A’.

Although not shown, a silicidation process may be further performed. For example, a metal layer may be formed within the slits, and the word lines 34A may be silicided (i.e., changed to be silicide) by reacting the metal layer with the word lines 34A using a thermal treatment process. Next, the remaining metal layer is removed. In this case, the performance of the memory device may be improved because resistance of the word lines is reduced by the silicidation process.

Next, an insulating layer 39 is filled in the slits.

Although the slit is illustrated as being formed every between strings adjacent to each other, the slit may be formed between some of the strings so that strings adjacent to each other share a source-side word line or a drain-side word line or both.

Accordingly, a plurality of memory cells stacked along the first channel layer CH1 filled within the pipe gate 32 and each of the second channel layers CH2 coupled to the first channel layer CH1 are formed.

In accordance with the first embodiment, an empty space may be prevented from being formed within the first trench when forming the layer for a channel because the width W5 or the depth D of the first trench is smaller than the diameter W6 of the second trench.

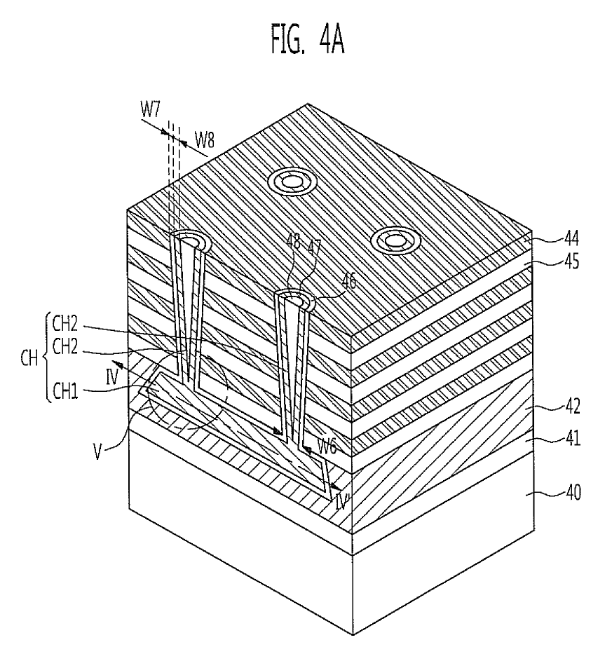

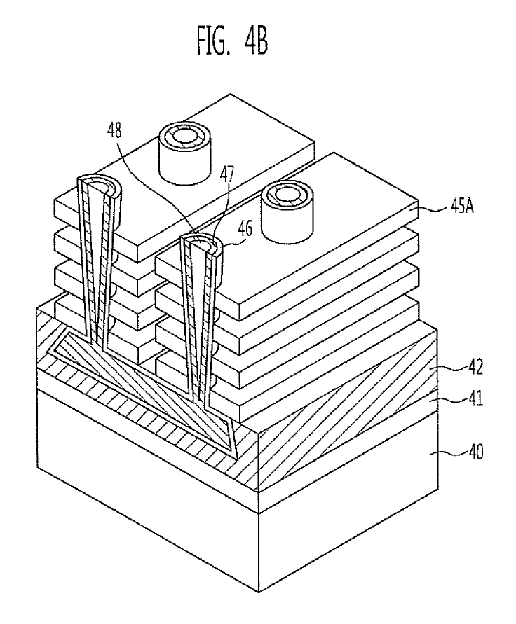

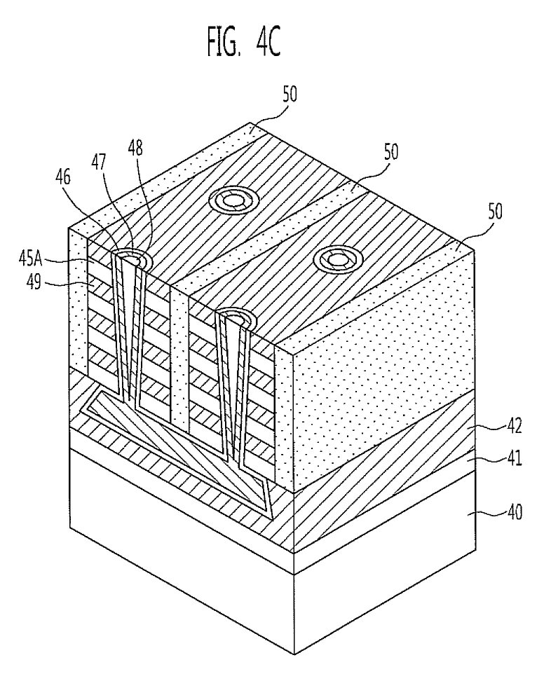

FIGS. 4A to 4C are perspective views illustrating a method of manufacturing a 3-D non-volatile memory device according to a second embodiment of the present invention.

In the second embodiment, it is described that the first and the second material layers are formed of a sacrificial layer and an interlayer insulating layer, respectively. A description of the contents of the second embodiment which are the same as those of the first embodiment is omitted, for simplicity.

As shown in FIG. 4A, a first interlayer insulating layer 41 and a pipe gate 42 are formed over a substrate 40. The pipe gate 42 is etched to form a first trench. The width W5 or the depth D of the first trench is smaller than the diameter W6 of a second trench to be formed in a subsequent process.

A first sacrificial layer (not shown) is filled in the first trench. Second sacrificial layers 44 and second interlayer insulating layers 45 are alternately formed over the pipe gate 42 within which the first sacrificial layer is filled. The second sacrificial layers 44 serve to secure regions where word lines are formed in a subsequent process. The second sacrificial layers 44 are made of material having a high etch selectivity to the second interlayer insulating layers 45. For example, the second sacrificial layer 44 may be formed of a nitride layer, and the second interlayer insulating layer 45 may be formed of an oxide layer.

The second sacrificial layers 44 and the second interlayer insulating layers 45 are etched to form second trenches coupled to the first trench.

After removing the first sacrificial layer exposed at the bottoms of the second trenches, a memory layer 46 is formed on the inside of the first trench and the second trenches. The memory layer 46 may include a charge blocking layer, a charge trap layer, and a tunnel insulating layer or may include a charge trap layer and a tunnel insulating layer. Furthermore, prior to the formation of the memory layer 46, a buffer layer for preventing the charge trap layer from being damaged in a subsequent process of removing the second sacrificial layers may be formed.

A layer 47 for a channel is formed on the tunnel insulating layer, thereby forming a first channel layer CH1 within the first trench and second channel layers CH2 within the second trenches. When depositing the layer 47 for a channel, the first channel layer CH1 within which the layer 47 for a channel is fully filled may be formed in the first trench, and the second channel layers CH2 each having an open central region may be formed within the second trenches. The insulating layer 48 is filled in the open central region of the second channel layer CH2.

As shown in FIG. 4B, the second sacrificial layers 44 and the second interlayer insulating layers 45 are etched to form slits. The second sacrificial layers 44 exposed at the inner walls of the slits are removed. In FIG. 4B, the etched second interlayer insulating layers are denoted by reference numeral ‘45A’.

As shown in FIG. 4C, a conductive layer is filled in the regions from which the second sacrificial layers 44 have been removed, thus forming word lines 49 stacked in multiple layers. The conductive layer may be a polysilicon layer or a metal layer, such as tungsten W.

Here, if a charge blocking layer is not formed within the second trenches, the charge blocking layer is formed on the insides of the regions from which the second sacrificial layers 44 have been removed before filling the conductive layer. In this case, the charge blocking layer is formed to surround the word lines 49. Furthermore, the charge blocking layer may be formed to couple the stacked memory cells. Meanwhile, if a buffer layer is formed within the second trenches, the charge blocking layer may be formed after exposing the charge trap layers by etching the buffer layer.

An insulating layer 50 is filled in the slits. Thus, a plurality of memory cells are stacked along the first channel layer CH1 filled in the pipe gate 42 and the second channel layers CH2 coupled to the first channel layer CH1.

In accordance with the second embodiment, an empty space may be prevented from being formed within the first trench when forming the layer 47 for a channel because the width W5 or the depth D of the first trench is smaller than the diameter W6 of the second trench.

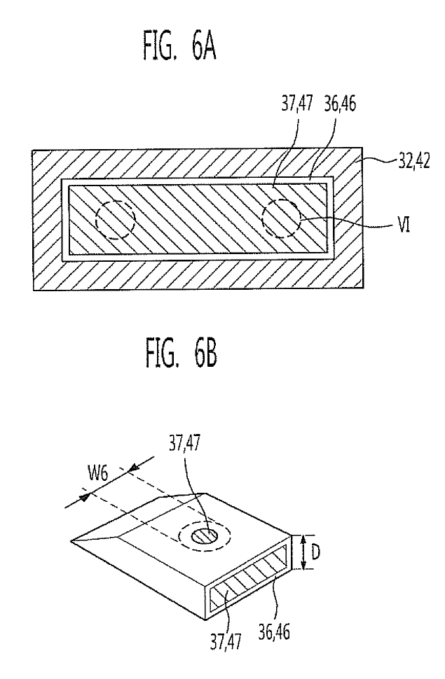

FIGS. 5A to 6B are enlarged views of the pipe channel region of the 3-D non-volatile memory device according to the first and the second embodiments of the present invention. FIGS. 5A and 6A are cross sectional views of the pipe channel region taken along line VI-VI′ in FIGS. 3B and 4A, and FIGS. 5B and 6B are perspective views of a region V in FIGS. 3B and 4A.

As shown in FIGS. 5A and 5B, the 3-D non-volatile memory device according to the first and the second embodiments of the present invention includes the first trench having the width W5 smaller than the diameter W6 of the second channel. In particular, the width W5 of the first trench preferably is smaller than twice the sum of the thickness W8 of the second channel layer CH2 and the thickness W7 of the memory layer 36 or 46 that surrounds the second channel layer CH2. Furthermore, the width W5 of the first trench preferably is greater than twice the thickness of the memory layer 36 or 46 that surrounds the first channel layer CH1.

As shown in FIGS. 6A and 6B, the 3-D non-volatile memory device according to the first and the second embodiments of the present invention includes the first trench having the depth D smaller than the diameter W6 of the second channel. In particular, the depth D of the first trench preferably is smaller than twice the sum of the thickness of the second channel layer CH2 and the thickness of the memory layer 36 or 46 that surrounds the second channel layer CH2. Furthermore, the depth D of the first trench preferably is greater than twice the thickness of the memory layer 36 or 46 that surrounds the first channel layer CH1.

If, as described above, the width W5 or the depth D of the first trench is controlled, the coupling parts VI of the first trench and the second trenches may be prevented from being filled before the layer 37 or 47 for a channel is fully filled in the first trench in the process of forming the layer 37 or 47 for a channel. That is, the layer 37 or 47 for a channel may be fully filled in the first trench. Furthermore, the coupling parts VI remain open until the layer 37 or 47 for a channel is fully filled in the first trench. Accordingly, after forming the layer 37 or 47 for a channel so that a central region is open within the first trench, the insulating layer may be filled in the open regions.

In the above embodiments, the width of the first trench is controlled or the depth of the first trench is controlled. In some embodiments, however, both the width and depth of the first trench may be controlled.

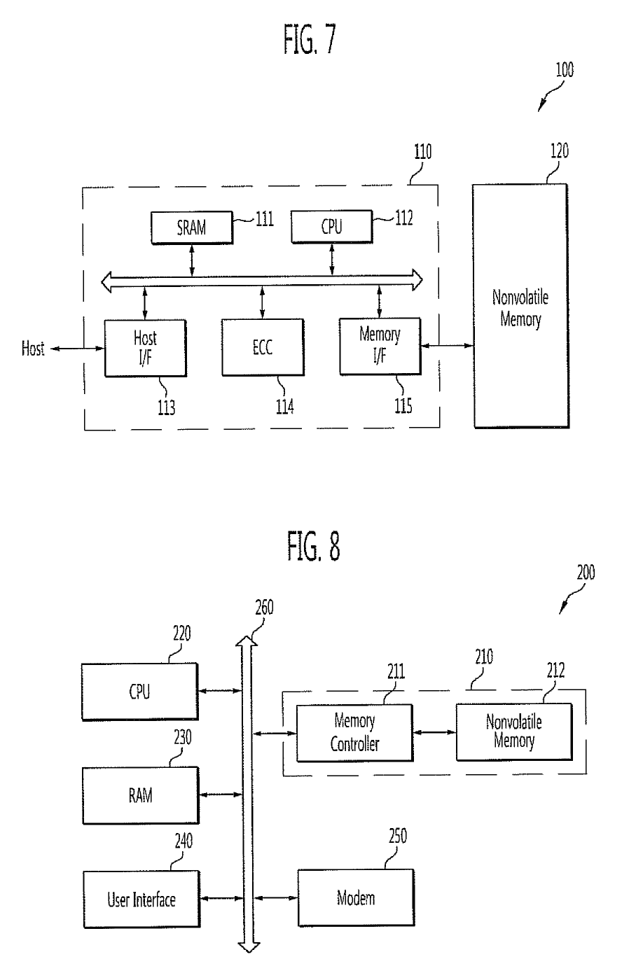

FIG. 7 shows the configuration of a memory system according to an embodiment of the present invention.

As shown in FIG. 7, the memory system 100 according to the embodiment of the present invention includes a non-volatile memory device 120 and a memory controller 110.

The non-volatile memory device 120 includes a cell array including the pipe gates in the first trenches as described above. In some embodiments, the non-volatile memory device 120 may be a multi-chip package including a plurality of flash memory chips.

The memory controller 110 controls the non-volatile memory device 120 and may include SRAM 111, a Central Processing Unit (CPU) 112, a host interface (I/F) 113, an ECC circuit 114, and a memory I/F 115. The SRAM 111 is used as the operating memory of the CPU 112. The CPU 112 performs an overall control operation for the data exchange of the memory controller 110. The host I/F 113 is equipped with the data exchange protocol of a host coupled to the memory system 100. Furthermore, the ECC circuit 114 detects and corrects errors included in data read out from the non-volatile memory device 120. The memory I/F 115 interfaces the memory controller 110 with the non-volatile memory device 120. The memory controller 110 may further include RCM for storing code data for an interface with the host.

The memory system 100 constructed as above may be a memory card or a Solid State Disk (SSD) in which the non-volatile memory device 120 and the controller 110 are combined. For example, if the memory system 100 is the SSD, the memory controller 110 may communicate with the outside (e.g., a host) through one of various interface protocols, such as USB, MMC, PCI-E, SATA, PATA, SCSI, ESDI, and IDE.

FIG. 8 shows the configuration of a computing system according to an embodiment of the present invention.

As shown in FIG. 8, the computing system 200 according to the embodiment of the present invention may include a CPU 220, RAM 230, a user interface 240, a modem 250, and a memory system 210 which are electrically coupled to a system bus 260. If the computing system 200 is a mobile device, the computing system 200 may further include a battery for supplying an operating voltage to the computing system 200. The computing system 200 may further include application chipsets, a Camera Image Processor (CIS), mobile DRAM, and so on.

The memory system 210 may include a non-volatile memory device 212 and a memory controller 211 constructed as described above with reference to FIG. 7.

In accordance with the embodiment of the present invention, the width of the trench for a pipe channel is smaller than the diameter of the trench for a memory channel. Accordingly, an empty space may not be formed within the pipe channel because the layer for a channel is fully filled in the trench for a pipe channel. Accordingly, the layer for a channel may be prevented from being agglomerated in a subsequent high-temperature thermal treatment process.

What is claimed is:

1. A 3-D non-volatile memory device, comprising:
a pipe gate having a first trench formed therein;
word lines stacked in multiple layers over the pipe gate;
second trenches coupled to the first trench and formed to penetrate the word lines;
a first channel layer formed within the first trench; and
second channel layers formed within the second trenches, respectively, and coupled to the first channel layer,
wherein a width or depth of the first trench is smaller than a diameter of each of the second trenches.

2. The 3-D non-volatile memory device of claim 1, further comprising a memory layer surrounding the first channel layer and the second channel layers.

3. The 3-D non-volatile memory device of claim 2, further comprising an insulating layer interposed between the memory layer and the pipe gate.

4. The 3-D non-volatile memory device of claim 3, wherein the width or the depth of the first trench is smaller than twice a sum of a thickness of the second channel layer and a thickness of the memory layer surrounding the second channel layers.

5. The 3-D non-volatile memory device of claim 3, wherein the width or depth of the first trench is greater than twice a thickness of the memory layer surrounding the first channel layer.

6. The 3-D non-volatile memory device of claim 1, wherein the first channel layer is fully filled in the first trench.

7. The 3-D non-volatile memory device of claim 1, wherein the second channel layer is fully filled in the second trench.

8. The 3-D non-volatile memory device of claim 1, wherein the second channel layer is formed on an inner wall of the second trench and an insulating layer is filled in the second trench having the second channel layer formed thereon.

9. The 3-D non-volatile memory device of claim 1, wherein the pipe gate has a double gate structure to surround an entire surface of the first channel layer.

10. A method of manufacturing a 3-D non-volatile memory device, comprising:
forming a first trench by etching a first pipe gate;
filling a first sacrificial layer within the first trench;
alternately forming first material layers and second material layers over the first pipe gate having the first sacrificial layer filled therein;
forming second trenches coupled to the first trench by etching the first material layers and the second material layers;
removing the first sacrificial layer exposed at bottoms of the second trenches; and
forming a first channel layer within the first trench and forming second channel layers coupled to the first channel layer within the second trenches, respectively,
wherein a width or depth of the first trench is smaller than a diameter of each of the second trenches.

11. The method of claim 10, wherein the first material layer and the second material layer are made of materials having a high etch selectivity therebetween.

12. The method of claim 10, further comprising:
removing the second material layers after the forming of the first channel layer and the second channel layers; and
filling an interlayer insulating layer or a conductive layer in regions from which the second material layers are removed.

13. The method of claim 10, wherein the forming of the first trench comprises:
forming a temporary trench by etching the first pipe gate; and
forming the first trench having a smaller width and depth than the temporary trench by forming a conductive layer or an insulating layer on an inner surface of the temporary trench.

14. The method of claim 10, further comprising:
forming a memory layer on inner surfaces of the first trench and the second trenches after the removing of the first sacrificial layer.

15. The method of claim 14, wherein the width or depth of the first trench is smaller than twice a sum of a thickness of the second channel layer and a thickness of the memory layer formed on the inner surfaces of the second trenches.

16. The method of claim 14, wherein the width or depth of the first trench is greater than twice a thickness of the memory layer formed on the inner surface of the first trench.

17. The method of claim 10, wherein the first channel layer is fully filled in the first trench.

18. The method of claim 10, wherein the second channel layer is fully filled in the second trench.

19. The method of claim 10, wherein the second channel layer is formed on an inner wall of the second trench and an insulating layer is filled in the second trench having the second channel layer formed thereon.

20. The method of claim 10, further comprising forming a second pipe gate on the first pipe gate having the first sacrificial layer filled therein, after the filling of the first sacrificial layer.
